(19) United States
(12) Patent Application Publication
(10) Pub. No.: US 2024/0428838 A1
(43) Pub. Date: Dec. 26, 2024

(54) SYNAPSE DEVICE INCLUDING FERROELECTRIC FIELD EFFECT TRANSISTOR AND NEURAL NETWORK APPARATUS INCLUDING THE SAME

(71) Applicant: Samsung Electronics Co., Ltd., Suwon-si (KR)

(72) Inventor: Sijung YOO, Suwon-si (KR)

(73) Assignee: Samsung Electronics Co., Ltd., Suwon-si (KR)

(21) Appl. No.: 18/748,706

(22) Filed: Jun. 20, 2024

(30) Foreign Application Priority Data
Jun. 20, 2023 (KR) 10-2023-0078854

(51) Int. Cl. G11C 11/22; G06N 3/0464; G11C 7/16; G11C 11/54; H01L 29/78; H10B 51/30

(52) U.S. Cl. CPC G11C 11/223; G06N 3/0464; G11C 7/16; G11C 11/2275; G11C 11/54; H01L 29/78391; H10B 51/30

(57) ABSTRACT

A synapse device including a ferroelectric field effect transistor, and a neural network apparatus including the same, are provided. The synapse device includes a first ferroelectric field effect transistor and a second ferroelectric field effect transistor electrically connected in parallel with the first ferroelectric field effect transistor, wherein the first ferroelectric field effect transistor may have a first coercive voltage, and the second ferroelectric field effect transistor may have a second coercive voltage that is greater than the first coercive voltage.

### CROSS-REFERENCE TO RELATED APPLICATION

This application is based on and claims priority under 35 U.S.C. § 119 to Korean Patent Application No. 10-2023-0078854, filed on Jun. 20, 2023, in the Korean Intellectual Property Office, the disclosure of which is incorporated by reference herein in its entirety.

### BACKGROUND

### 1. Field

The disclosure relates to a synapse device including a ferroelectric field effect transistor, and a neural network apparatus including the same.

### 2. Description of the Related Art

There has been an increased interest in neuromorphic processors that are configured to perform neural network operations. A neuromorphic processor may be used as a neural network apparatus for driving various neural networks such as a convolutional neural network (CNN), a recurrent neural network (RNN), and a feedforward neural network (FNN) and may be utilized in fields including data classification or image recognition.

Such a neuromorphic processor may include a plurality of synapse devices for storing weights. The synapse devices may be implemented with various elements. Recently, a simple structure of nonvolatile memory has been proposed as a synapse device for a neuromorphic processor to reduce the area of the synapse device and reduce power consumption. Meanwhile, implementing a linear relationship between an input value input to the synapse device and a weight recorded in the synapse device is a factor for improving the performance of a neuromorphic processor.

### SUMMARY

Provided is a synapse device having a linear response characteristic with respect to an applied voltage.

In addition, provided is a neural network apparatus including a synapse device having a linear response characteristic to an applied voltage.

Additional aspects will be set forth in part in the description which follows and, in part, will be apparent from the description, or may be learned by practice of the presented embodiments of the disclosure.

According to an aspect of at least one embodiment, a synapse device includes a first ferroelectric field effect transistor including a source region, a drain region, and a gate electrode, and a second ferroelectric field effect transistor including a source region, a drain region, and a gate electrode, wherein the gate electrodes of the first ferroelectric field effect transistor and the second ferroelectric field effect transistor are electrically connected to each other, the source regions of the first ferroelectric field effect transistor and the second ferroelectric field effect transistor are electrically connected to each other, and the drain regions of the first ferroelectric field effect transistor and the second ferroelectric field effect transistor are electrically connected to each other, and the first ferroelectric field effect transistor may have a first coercive voltage, and the second ferroelectric field effect transistor may have a second coercive voltage greater than the first coercive voltage.

The first ferroelectric field effect transistor and the second ferroelectric field effect transistor may each configured to be switchable between a first state having a first threshold voltage and a second state having a second threshold voltage that is greater than the first threshold voltage.

Each of the first ferroelectric field effect transistor and the second ferroelectric field effect transistor further includes: a channel region between the source region and the drain region; and a ferroelectric layer between the channel region and the gate electrode, wherein the gate electrode faces the channel region.

A ferroelectric layer of the first ferroelectric field effect transistor may have a first thickness, and a ferroelectric layer of the second ferroelectric field effect transistor may have a second thickness that is greater than the first thickness.

A ferroelectric layer of the first ferroelectric field effect transistor and a ferroelectric layer of the second ferroelectric field effect transistor may have at least of different ferroelectric materials from each other or different compositions from each other.

A ferroelectric layer of the first ferroelectric field effect transistor and a ferroelectric layer of the second ferroelectric field effect transistor may be heat-treated at different heat treatment atmospheres or different heat treatment temperatures.

The channel region of the first ferroelectric field effect transistor and the channel region of the second ferroelectric field effect transistor may have substantially the same material and size.

The synapse device may further include a gate terminal electrically connected to the gate electrodes of the first ferroelectric field effect transistor and the second ferroelectric field effect transistor through a first shared wire; a source terminal electrically connected to the source regions of the first ferroelectric field effect transistor and the second ferroelectric field effect transistor through a second shared wire; and a drain terminal electrically connected to the drain regions of the first ferroelectric field effect transistor and the second ferroelectric field effect transistor through a third shared wire.

The first ferroelectric field effect transistor and the second ferroelectric field effect transistor may have substantially the same electrical conductance when turned on.

The synapse device may be configured to switch between a plurality of discrete electrical conductance values based on a voltage applied to the synapse device and the plurality of discrete electrical conductance values are distinguished from each other.

According to another aspect of at least one embodiment, a neural network apparatus includes a plurality of input lines, a plurality of output lines, a plurality of program lines, and a two-dimensional array of synapse devices, wherein each of the synapse devices is electrically connected to a corresponding input line among the plurality of input lines, a corresponding program line among the plurality of program lines, and a corresponding output line among the plurality of output lines, and each of the synapse devices includes a first ferroelectric field effect transistor including a source region, a drain region, and a gate electrode; and a second ferroelectric field effect transistor including a source region, a drain region, and a gate electrode, wherein the gate electrodes of the first ferroelectric field effect transistor and the second ferroelectric field effect transistor are electrically connected to each other, the source regions of the first ferroelectric field effect transistor and the second ferroelectric field effect transistor are electrically connected to each other, the drain regions of the first ferroelectric field effect transistor and the second ferroelectric field effect transistor are electrically connected to each other, the first ferroelectric field effect transistor has a first coercive voltage, and the second ferroelectric field effect transistor may have a second coercive voltage that is greater than the first coercive voltage.

The gate terminal of each of the synapse devices may be electrically connected to the corresponding program line, the source terminal of each of the synapse devices is electrically connected to the corresponding input line, and the drain terminal of each of the synapse devices is electrically connected to the corresponding output line.

The neural network apparatus further includes an input circuit configured to provide an input voltage to the plurality of input lines, a program line driver for providing a program voltage or a read voltage to the plurality of program lines, and an output circuit for outputting signals from the plurality of output lines, wherein each of the synapse devices is configured to switch between at least a 0th electrical conductance, a first electrical conductance, and a second electrical conductance based on a voltage applied to the synapse device, and the values of the 0th electrical conductance to the second electrical conductance may be discontinuous values configured to represent an arithmetical progression.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a diagram for explaining an architecture of a neural network according to at least one embodiment;

FIG. 2 is a diagram for explaining an operation performed in a neural network according to at least one embodiment;

FIG. 3 is a block diagram schematically illustrating a structure of a neural network apparatus according to at least one embodiment;

FIG. 4 illustrates a circuit structure of a synapse device according to at least one embodiment;

FIGS. 5A and 5B are cross-sectional views schematically showing a structure of a plurality of ferroelectric field effect transistors of a synapse device according to at least one embodiment;

FIGS. 6A and 6B are diagrams illustrating a learning operation and an inference operation of a synapse device according to at least one embodiment;

FIG. 7 is a graph illustrating a relationship between a program voltage applied to a synapse device according to at least one embodiment and electrical conductance of the synapse device;

FIGS. 8 and 9 are diagrams illustrating a learning operation and an inference operation of a neural network apparatus according to at least one embodiment; and

FIG. 10 is a block diagram schematically illustrating an example structure of an electronic apparatus including a neural network apparatus.

### DETAILED DESCRIPTION

Reference will now be made in detail to some embodiments, examples of which are illustrated in the accompanying drawings, wherein like reference numerals refer to like elements throughout. In this regard, the present embodiments may have different forms and should not be construed as being limited to the descriptions set forth herein. Additionally, in the following drawings, the same reference numerals refer to the same components, and the size of each component in the drawings may be exaggerated for clarity and convenience of description. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

Hereinafter, a synapse device including a ferroelectric field effect transistor and a neural network apparatus including the synapse device will be described in detail with reference to the accompanying drawings.

Hereinafter, the term “upper portion” or “on” may also include “to be present on a non-contact basis” as well as “to be in directly contact with”. The singular expression includes multiple expressions unless the context clearly implies otherwise. In addition, when a part “includes” a component, this means that it may further include other components, not excluding other components unless otherwise opposed. Additionally, spatially relative terms, such as “beneath,” “below,” “lower,” “under,” “above,” “upper,” and the like, may be used herein for ease of explanation to describe one element or feature's relationship to another element or feature as illustrated in the figures. It will be understood that the spatially relative terms are intended to encompass different orientations of the device in use or in operation, in addition to the orientation depicted in the figures. For example, device may be otherwise oriented, for example, rotated 90 degrees or at other orientations, and the spatially relative descriptors used herein should be interpreted accordingly.

The use of the term “the” and similar indicative terms may correspond to both singular and plural. If there is no explicit description of an order for steps that make up a method or vice versa, these steps can be done in an appropriate order and are not necessarily limited to the order described.

Further, the terms “unit”, “module” or the like mean a unit that processes at least one function or operation, which may be implemented in processing circuitry, such as hardware, software or in a combination of hardware and software. For example, the processing circuitry more specifically may include (and/or be included in), but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

The connection or connection members of lines between the components shown in the drawings exemplarily represent functional connection and/or physical or circuit connections, and may be replaceable or represented as various additional functional connections, physical connections, or circuit connections in an actual device.

The use of all examples or exemplary terms is simply to describe technical ideas in detail, and the scope is not limited by these examples or exemplary terms unless the scope is limited by the claims. Additionally, when the terms “about” or “substantially” are used in this specification in connection with a numerical value, it is intended that the associated numerical value includes a manufacturing tolerance (e.g., ±10%) around the stated numerical value. Further, regardless of whether numerical values are modified as “about” or “substantially,” it will be understood that these values should be construed as including a manufacturing or operational tolerance (e.g., ±10%) around the stated numerical values. When referring to “C to D”, this means C inclusive to D inclusive unless otherwise specified.

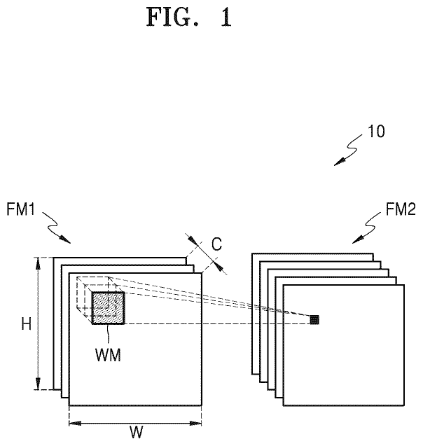

FIG. 1 is a diagram for explaining an architecture of a neural network according to at least one embodiment. Referring to FIG. 1, the neural network 10 according to at least one embodiment may also be represented by a mathematical model using nodes and edges. The neural network 10 may be an architecture of a deep neural network (DNN) or n-layers neural networks. The DNN or n-layers neural networks may include convolutional neural network (CNN), recurrent neural network (RNN), feedback neural network (FNN), long short-term memory (LSTM), stacked neural network (SNN), state-space dynamic neural network (SSDNN), deep belief network (DBN), restricted Boltzmann machine (RBM), and the like. For example, the neural network 10 may be implemented as a CNN, but is not limited thereto. The neural network 10 of FIG. 1 may correspond to some layers of the CNN. Accordingly, the neural network 10 may correspond to a convolution layer, a pooling layer, a fully connected layer, or the like of the CNN. However, hereinafter, for convenience of explanation, it will be assumed that the neural network 10 corresponds to the convolution layer of the CNN.

In the convolution layer, a first feature map FM1 may correspond to an input feature map, and a second feature map FM2 may correspond to an output feature map. The feature map may include a data set in which various characteristics of input data are expressed. The feature maps FM1 and FM2 may be high-dimensional matrices of two-dimensional (or more) and have activation parameters, respectively. When the feature maps FM1 and FM2 correspond to, for example, three-dimensional feature maps, the feature maps FM1 and FM2 have a width W (also referred to as a column), a height H (or a row), and a depth C. In this case, the depth C may correspond to the number of channels.

In the convolution layer, a convolution operation on the first feature map FM1 and a weight map WM may be performed, and as a result, the second feature map FM2 may be generated. The weight map WM may filter the first feature map FM1 and is referred to as a weight filter or a weight kernel. In one example, the depth of the weight map WM (e.g., the number of channels) is the same as the depth of the first feature map FM1 (e.g., the number of channels). The weight map WM is shifted to transverse the first feature map FM1 as a sliding window. During each shift, each of the weights included in the weight map WM may be multiplied by and added to all feature values in a region overlapping the first feature map FM1. As the first feature map FM1 and the weight map WM are convoluted, one channel of the second feature map FM2 may be generated.

Although one weight map WM is illustrated in FIG. 1, a plurality of weight maps may be substantially convoluted with the first feature map FM1 to generate a plurality of channels of the second feature map FM2. Meanwhile, the second feature map FM2 of the convolution layer may be an input feature map of the next layer. For example, the second feature map FM2 may be an input feature map of a pooling layer. However, the embodiment is not limited thereto.

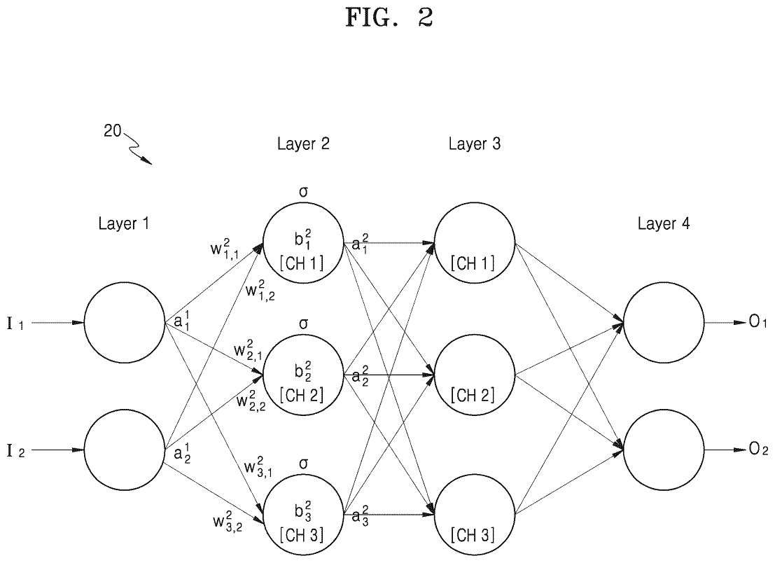

FIG. 2 is a diagram for explaining an arithmetic operation performed in a neural network according to at least one embodiment. Referring to FIG. 2, the neural network 20 may have a structure including an input layer, hidden layers, and an output layer, perform an operation based on received input data (e.g., I₁ and I₂), and generate output data (e.g., 01 and O₂) based on the arithmetic operation performance result.

As described above, the neural network 20 may include a DNN or n-layers neural network including two or more hidden layers. For example, as shown in FIG. 2, the neural network 20 may be a DNN including an input layer (Layer 1), two hidden layers (Layer 2 and Layer 3), and an output layer (Layer 4). When the neural network 20 is implemented as a DNN architecture, it includes more layers configured to process valid information, so the neural network 20 may process more complex datasets than a neural network with a single layer. Meanwhile, the neural network 20 is illustrated as including four layers, but this is only an example, and the neural network 20 may include less or more layers, or may include less or more channels. In other words, the neural network 20 may include layers of various structures different from those illustrated in FIG. 2.

Each of the layers included in the neural network 20 may include a plurality of channels. The channel may correspond to a plurality of artificial nodes, known as a neuron, a processing element (PE), a unit, or similar terms. For example, as shown in FIG. 2, Layer 1 may include two channels (nodes), and each of Layer 2 and Layer 3 may include three channels. However, this is only an example, and each of the layers included in the neural network 20 may include various numbers of channels (nodes).

Channels included in each of the layers of the neural network 20 may be connected to each other to process data. For example, one channel may receive data from other channels to perform an arithmetic operation and may output the arithmetic operation result to other channels.

The input and output of the channel may be referred to as an input activation and an output activation, respectively. In other words, the activation may be a parameter corresponding to an output of one channel and simultaneously inputs of channels included in the next layer. Meanwhile, each of the channels may determine its own activation based on activations and weights received from channels included in the previous layer. The weight is a parameter used to calculate output activation in each channel and may be a value allocated to a connection relationship between channels.

Each of the channels may be processed by a computational unit or processing element that receives an input and outputs an output activation, and the input-output of each of the channels may be mapped. For example, σ is an activation function, wⱼₖⁱ is the weight from the k-th of the j-th channel included in the (i−1)th layer to the j-th channel included in the i-th layer, bⱼⁱ is the bias of the j-th channel included in the i-th layer, and when aⱼⁱ is the activation of the j-th channel included in the i-th layer, the activation aⱼⁱ may be calculated by using the following Equation 1.

$${a}_{j}^{i} = σ ( {\sum }_{k} ( {w}_{jk}^{i} \times {a}_{k}^{i - 1} ) + {b}_{j}^{i} ) \qquad [ Equation 1 ]$$

As shown in FIG. 2, the activation of the first channel CH1 of the second layer Layer 2 may be represented by a₁². In addition, a₁² may have a value of a₁²=σ(w_{1,1}²×a₁¹+w_{1,2}²×a₂¹+b₁²) according to Equation 1. The activation function a may be a Rectified Linear Unit (ReLU), but is not limited thereto. For example, the activation function a may be a sigmoid, a hyperbolic tangent tanh, a maxout, and/or the like.

As described above, in the neural network 20, numerous datasets are exchanged between multiple interconnected channels and undergo an arithmetic operation process passing through the layer. In such an arithmetic operation process, a number of multiply-accumulate (MAC) operations are performed, and a number of memory access operations to load activations and weights, which are operands of MAC operations at an appropriate point in time, should be performed together.

Meanwhile, a typical digital computer uses a Von Neumann architecture that separates a computational unit and a memory and includes a common data bus for data transfer between two separated blocks. Therefore, in the process of performing the neural network 20 in which the data movement and arithmetic operation are continuously repeated, a large amount of time may be required for data transmission, and excessive power may be consumed. To overcome this problem, an in-memory computing neural network apparatus is described below as an example architecture that integrates memory and operation units for performing MAC operations into one block.

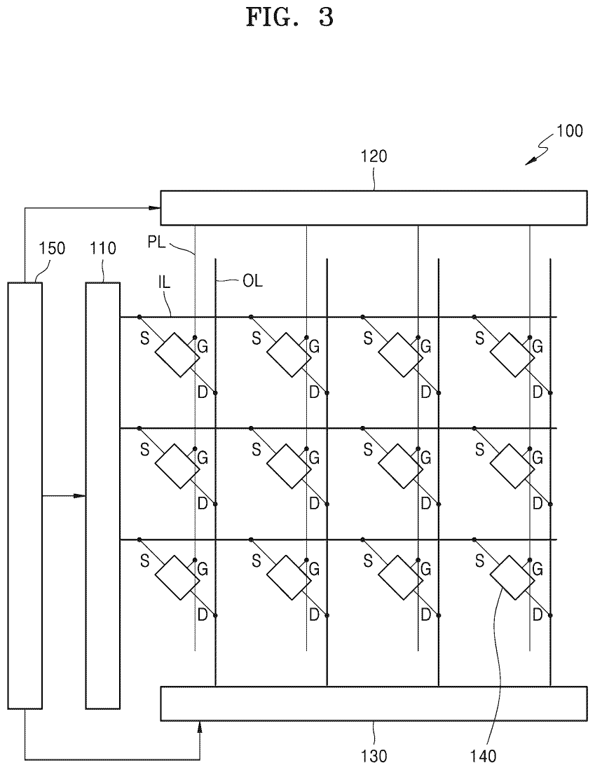

FIG. 3 is a block diagram schematically illustrating a structure of a neural network apparatus according to at least one embodiment; The neural network apparatus 100 according to FIG. 3 is an in-memory computing neural network apparatus in which memory and computation units for performing MAC operations are integrated into one. Referring to FIG. 3, the neural network apparatus 100 may include a plurality of input lines IL, a plurality of output lines OL, a plurality of program lines PL, an input circuit 110 providing input voltages to the plurality of input lines IL, a program line driver 120 providing program voltage and/or read voltage to the plurality of program lines PL, an output circuit 130 outputting signals from the plurality of output lines OL, and a plurality of synapse devices 140. The output circuit 130 may include an analog to digital converter (ADC) connected to each of the plurality of output lines OL. Although not illustrated for convenience, the neural network apparatus 100 may further include other general-purpose components in addition to those illustrated in FIG. 3. In addition, the neural network apparatus 100 may further include a control circuit 150 that controls the operation of the input circuit 110, the program line driver 120, and the output circuit 130. The input circuit 110, the program line driver 120, the output circuit 130, and the control circuit 150 may be manufactured as separate circuits, and/or may be implemented as one driving circuit on a circuit board.

The plurality of input lines IL may be provided in parallel with each other, and may extend in a row direction or a column direction. One end of each of the plurality of input lines IL may be electrically connected to the input circuit 110 to receive an input voltage from the input circuit 110. In addition, the plurality of program lines PL may be provided parallel to each other and may extend in a row direction or a column direction. One end of each of the plurality of program lines PL may be electrically connected to the program line driver 120 to receive program voltage from the program line driver 120. The plurality of output lines OL may be provided parallel to each other and may extend in a row direction or a column direction. One end of each of the plurality of output lines OL may be electrically connected to the output circuit 130 to provide an output signal from each of the synapse devices 140 to the output circuit 130.

In FIG. 3, the plurality of input lines IL are provided to cross the plurality of program lines PL and the plurality of output lines OL, and the plurality of program lines PL and the plurality of output lines OL are provided in parallel with each other. However, this is only one example of the various arrangement methods of the plurality of input lines IL, the plurality of output lines OL, and the plurality of program lines PL, and is not necessarily limited thereto. For example, the plurality of input lines IL and the plurality of program lines PL may be provided parallel to each other, and the plurality of output lines OL may be provided to cross the plurality of input lines IL and the plurality of program lines PL. Alternatively, the plurality of input lines IL and the plurality of output lines OL may be provided parallel to each other, and the plurality of program lines PL may be provided to cross the plurality of input lines IL and the plurality of output lines OL.

The plurality of synapse devices 140 may be provided in the form of a two-dimensional array in row and column directions. Each of the plurality of synapse devices 140 may be provided at intersections where at least two of the plurality of input lines IL, the plurality of output lines OL, and the plurality of program lines PL intersect. In addition, each of the plurality of synapse devices 140 may include a gate terminal G, a source terminal S, and a drain terminal D.

Each of the plurality of synapse devices 140 is electrically connected to one corresponding input line among the plurality of input lines IL, one corresponding program line among the plurality of program lines PL, and one corresponding output line among the plurality of output lines OL. For example, the gate terminal G of each of the plurality of synapse devices 140 may be electrically connected to one corresponding program line among the plurality of program lines PL. The source terminal S of each of the plurality of synapse devices may be electrically connected to one corresponding input line among a plurality of input lines IL. The drain terminal D of each of the plurality of synapse devices 140 may be electrically connected to one corresponding output line among the plurality of output lines OL.

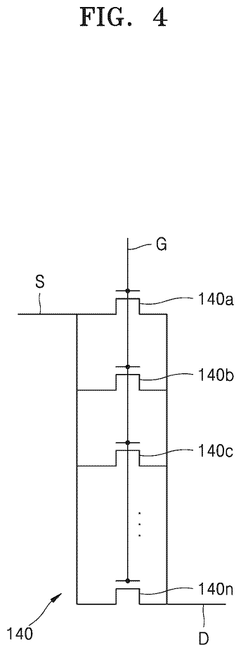

FIG. 4 illustrates a circuit structure of a synapse device 140 according to at least one embodiment. Referring to FIG. 4, one synapse device 140 may include a plurality of ferroelectric field effect transistors which are electrically connected in parallel with each other. For example, the synapse device 140 may include first to n-th ferroelectric field effect transistors 140a, 140b, 140c, . . . , and 140n, and the first to n-th ferroelectric field effect transistors 140a, 140b, 140c, . . . , and 140n may be electrically connected in parallel with each other. By saying that the first to n-th ferroelectric field effect transistors 140a, 140b, 140c, . . . , and 140n are electrically connected in parallel with each other, it is meant that the gate electrodes of the first to n-th ferroelectric field effect transistors 140a, 140b, 140c, . . . , and 140n are electrically connected with each other, the source regions thereof are electrically connected with each other, and the drain regions thereof are electrically connected with each other. For example, the gate electrodes of the first to n-th ferroelectric field effect transistors 140a, 140b, 140c, . . . , and 140n may be electrically connected to the gate terminal G of one synapse device 140 through one wire, the source regions thereof may be electrically connected to the source terminal S of the one synapse device 140 through one wire, and the drain regions thereof may be electrically connected to the drain terminal D of the one synapse device 140 through one wire. One synapse device 140 may include, for example, three or more ferroelectric field effect transistors.

The first to n-th ferroelectric field effect transistors 140a, 140b, 140c, . . . , and 140n are field effect transistors each having a ferroelectric layer provided between a channel region and a gate electrode of each of the field effect transistors. The ferroelectric material is a material that maintains a spontaneous polarization by aligning an internal electric dipole moment even if an electric field is not applied thereto from the outside. Depending on the polarization direction in the ferroelectric layer, the first to n-th ferroelectric field effect transistors 140a, 140b, 140c, . . . , and 140n may be configured to switch between a first state with a relatively low first threshold voltage and a second state with a second threshold voltage higher than the first threshold voltage. The ferroelectric material undergoes rapid polarization switching at a coercive voltage. Therefore, the threshold voltages of the first to n-th ferroelectric field effect transistors 140a, 140b, 140c, . . . , and 140n may be adjusted by applying a coercive voltage to the gate electrode. For example, when a positive (+) coercive voltage is applied to the gate electrodes of the first to n-th ferroelectric field effect transistors 140a, 140b, 140c, . . . , and 140n, the first to n-th ferroelectric field effect transistors 140a, 140b, 140c, . . . , and 140n have a relatively low first threshold voltage. Meanwhile, when a negative (−) coercive voltage is applied to the gate electrodes of the first to n-th ferroelectric field effect transistors 140a, 140b, 140c, . . . , and 140n, the first to n-th ferroelectric field effect transistors 140a, 140b, 140c, . . . , and 140n have a second threshold voltage greater than the first threshold voltage. Therefore, the first to n-th ferroelectric field effect transistors 140a, 140b, 140c, . . . , and 140n may be switchable between the first state and the second state depending on the voltage applied to the gate electrode.

In the synapse device 140 according to embodiments, the first to n-th ferroelectric field effect transistors 140a, 140b, 140c, . . . , and 140n may have different coercive voltages. For example, the first ferroelectric field effect transistor 140a has a first coercive voltage Vc1, the second ferroelectric field effect transistor 140b has a second coercive voltage Vc2 higher than the first coercive voltage Vc1, the third ferroelectric field effect transistor 140c has a third coercive voltage Vc3 higher than the second coercive voltage Vc2, and the n-th ferroelectric field effect transistor 140n may have the highest n-th coercive voltage Vcn.

Then, the threshold voltages of the first to n-th ferroelectric field effect transistors 140a, 140b, 140c, . . . , and 140n may be individually controlled according to the strength of the program voltage applied to the gate terminal G of the synapse device 140. For example, when the strength of the program voltage is greater than the first coercive voltage Vc1 and less than the second coercive voltage Vc2, only the first ferroelectric field effect transistor 140a may be in the first state with a relatively low first threshold voltage, and the remaining ferroelectric field effect transistors may be in the second state with a relatively high second threshold voltage. When the strength of the program voltage is greater than the second coercive voltage Vc2 and less than the third coercive voltage Vc3, only the first ferroelectric field effect transistor 140a and the second ferroelectric field effect transistor 140b may be in a first state having a relatively low first threshold voltage. When the strength of the program voltage is greater than the n-th coercive voltage Vcn, all ferroelectric field effect transistors 140a, 140b, 140c, . . . , and 140n become in a first state having a relatively low first threshold voltage. In addition, when the strength of the program voltage is lower than the negative n-th coercive voltage −Vcn, all ferroelectric field effect transistors 140a, 140b, 140c, . . . , and 140n may be in a second state with a relatively high second threshold voltage. Thus, the output of the synapse 140 may be adjusted based on the strength of the program voltage applied to the gate terminal G, as described below in further detail.

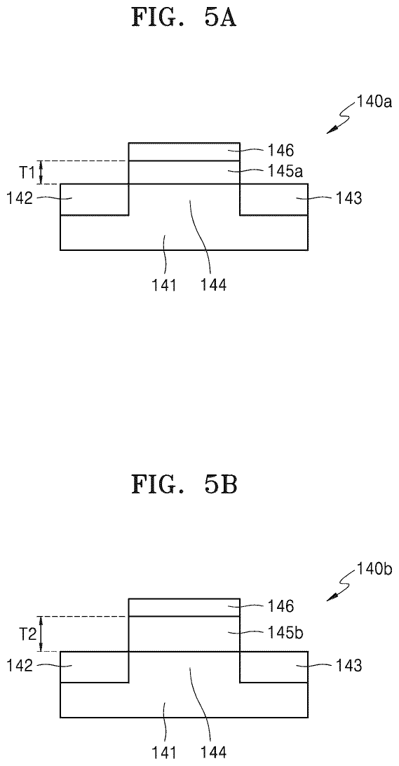

FIGS. 5A and 5B are cross-sectional views schematically showing a structure of a plurality of ferroelectric field effect transistors of a synapse device 140 according to at least one embodiment. Referring to FIGS. 5A and 5B, each of the first ferroelectric field effect transistor 140a and the second ferroelectric field effect transistor 140b may include a source region 142, a drain region 143, a channel region 144 provided between the source region 142 and the drain region 143, a ferroelectric layer 145a and 145b provided on an upper surface of the channel region 144, and a gate electrode 146 provided on an upper surface of the ferroelectric layer 145. The gate electrode 146 is provided to face the channel region 144, and the ferroelectric layer 145a and 145b may be provided between the channel region 144 and the gate electrode 146. In addition, each of the first ferroelectric field effect transistor 140a and the second ferroelectric field effect transistor 140b may further include a substrate 141. The source region 142 and the drain region 143 may be provided on both sides of the upper surface of the substrate 141. The channel region 144 may be a partial region of an upper portion of the substrate 141.

Although not illustrated, each of the first ferroelectric field effect transistor 140a and the second ferroelectric field effect transistor 140b may further include a source electrode and a drain electrode provided on the source region 142 and the drain region 143, respectively. In addition, additional functional layers for reducing contact resistance between the semiconductor and the metal or preventing metal diffusion may be further provided between the source region 142 and the source electrode and between the drain region 143 and the drain electrode.

In at least some embodiments, the source region 142 and the drain region 143 may be doped with a first conductance type, and the substrate 141 may be doped with a second conductance type electrically opposed to the first conductance type. For example, the substrate 141 may include a p-type semiconductor, the source region 142 and the drain region 143 may include an n-type semiconductor, or the substrate 141 may include an n-type semiconductor, and the source region 142 and the drain region 143 may include a p-type semiconductor. The substrate 141 may be doped at a relatively low concentration of about 10¹⁴ to 10¹⁸/cm³, while the source region 142 and the drain region 143 may be doped at a relatively high concentration of about 10¹⁹ to 10²¹/cm³ for low resistance. The source region 142 and the drain region 143 may be formed by doping both sides of the upper portion of the substrate 141, respectively. In at least some embodiments, a region of the upper region of the substrate 141 (e.g., where the source region 142 and the drain region 143 are not formed) defines the channel region 144. Accordingly, the channel region 144 may be provided between the source region 142 and the drain region 143.

The substrate 141, the source region 142, and the drain region 143 may include a semiconductor of at least one of: Group IV semiconductors such as silicon (Si), germanium (Ge), and SiGe; Group III-V compound semiconductors such as GaN, SiC, GaAs, InGaAs, and GaP; Group II-VI compound semiconductors; oxide semiconductors such as ZnO, SnO, GaO, InO, InGaZnO, and ZnSnO; two-dimensional material semiconductors such as MoS₂, SnS₂, and WTe₂; and/or the like. When the substrate 141, source region 142, and drain region 143 include Si, Ge, SiGe, etc., the substrate 141 may be doped with at least one dopant of B, Al, Ga, In, etc., and the source region 142 and drain region 143 may be doped with at least one dopant of P, As, Sb, etc. In these cases, the first ferroelectric field effect transistor 140a and the second ferroelectric field effect transistor 140b become n-channel metal oxide semiconductor (NMOS) field effect transistors. Alternatively, the substrate 141 may be doped with at least one dopant of P, As, Sb, etc., and the source region 142 and the drain region 143 may be doped with at least one dopant of B, Al, Ga, In, etc. In these cases, the first ferroelectric field effect transistor 140a and the second ferroelectric field effect transistor 140b become p-channel metal oxide semiconductor (PMOS) field effect transistors.

The gate electrode 146 may have conductance of approximately 1 MΩ/square or less. The gate electrode 146 may include one or more conductive materials selected from metals, metal nitrides, metal carbides, polysilicon, and/or combinations thereof. For example, the metals may include aluminum (Al), tungsten (W), molybdenum (Mo), titanium (Ti), tantalum (Ta), etc.; the metal nitrides may include titanium nitride (TiN), tantalum nitride (TaN), etc.; and the metal carbides may include aluminum or silicon doped (or containing) metal carbides (for example, TiAlC, TaAlC, TiSiC, TaSiC, etc.). The gate electrode 146 may have a structure in which a plurality of materials are stacked. For example, the gate electrode 146 may have a laminated structure of a metal nitride layer/metal layer such as TiN/Al or a laminated structure of a metal nitride layer/metal carbide layer/metal layer such as TiN/TiAlC/W. The gate electrode 146 may include a titanium nitride (TiN) layer or molybdenum (Mo), and the example may be used in various modifications. The gate electrode 146 may include a conductive two-dimensional material in addition to the materials described above. For example, the conductive two-dimensional material may include at least one of graphene, black phosphorus, amorphous boron nitride, two-dimensional hexagonal boron nitride (h-BN), and phosphorene.

The ferroelectric layer 145 may include a ferroelectric material. For example, the ferroelectric material of the ferroelectric layer 145 may include at least one material selected from among MgZnO, AlScN, BaTiO₃, Pb(Zr, Ti)O₃, SrBiTaO₇, polyvinylidene fluoride (PVDF), and metal oxides. The metal oxides may include at least one material selected from among an oxide of Si, an oxide of Al, an oxide of Hf, and an oxide of Zr doped with at least one dopant selected from Si, Al, Y, La, Gd, Mg, Ca, Sr Ba, Ti, Zr, Hf, and N. The ferroelectric material may include a ferroelectric phase of the ferroelectric material.

The coercive voltages of the first to n-th ferroelectric field effect transistors 140a, 140b, 140c, . . . , and 140n may be selected in various ways. For example, the ferroelectric layers 145 of the first to n-th ferroelectric field effect transistors 140a, 140b, 140c, . . . , and 140n may have different thicknesses. As shown in FIGS. 5A and 5B, the ferroelectric layer 145a of the first ferroelectric field effect transistor 140a may have a first thickness T1, and the ferroelectric layer 145b of the second ferroelectric field effect transistor 140b may have a second thickness T2 greater than the first thickness T1. Similarly, the ferroelectric layer 145 of the third ferroelectric field effect transistor 140c may have a third thickness greater than the second thickness T2, and the ferroelectric layer 145 of the n-th ferroelectric field effect transistor 140n may have the greatest n-th thickness.

In another example, the ferroelectric layers 145 of the first to n-th ferroelectric field effect transistors 140a, 140b, 140c, . . . , and 140n may have different ferroelectric materials or different compositions. In another example, after depositing the ferroelectric layer 145, heat treatment conditions may be differently selected for the ferroelectric layers 145 of the first to n-th ferroelectric field effect transistors 140a, 140b, 140c, . . . , and 140n in a subsequent process. For example, the ferroelectric layers 145 of the first to n-th ferroelectric field effect transistors 140a, 140b, 140c, . . . , and 140n may be heat treated at different heat treatment atmospheres or different heat treatment temperatures, e.g., to induce different concentrations of the ferroelectric phase and/or different coercive voltages.

Except for the ferroelectric layers 145, other configurations of the first to n-th ferroelectric field effect transistors 140a, 140b, 140c, . . . , and 140n may be the same. For example, the substrates 141 of the first to n-th ferroelectric field effect transistors 140a, 140b, 140c, . . . , and 140n have the same material and size each other, the source regions 142 of the first to n-th ferroelectric field effect transistors 140a, 140b, 140c, . . . , and 140n have the same material and size each other, the drain regions 143 of the first to n-th ferroelectric field effect transistors 140a, 140b, 140c, . . . , and 140n have the same material and size each other, and the channel regions 144 of the first to n-th ferroelectric field effect transistors 140a, 140b, 140c, . . . , and 140n may have the same material and size each other.

Meanwhile, FIGS. 5A and 5B illustrate that the first and second ferroelectric field effect transistors 140a and 140b each have a planar channel region 144, but the configuration of the plurality of ferroelectric field effect transistors of the synapse device 140 is not necessarily limited thereto. For example, the first to n-th ferroelectric field effect transistors 140a, 140b, 140c, . . . , and 140n may also be implemented as FinFET, gate-all-round FET (GAAFET), multi-bridge channel FET (MBCFET) with a three-dimensional channel structure, and/or the like.

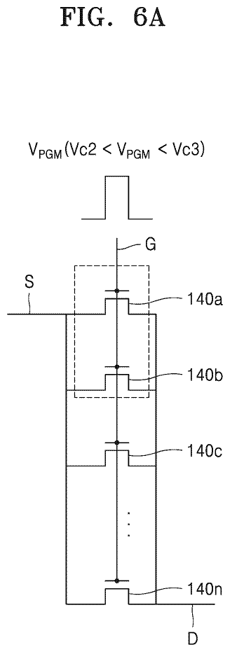

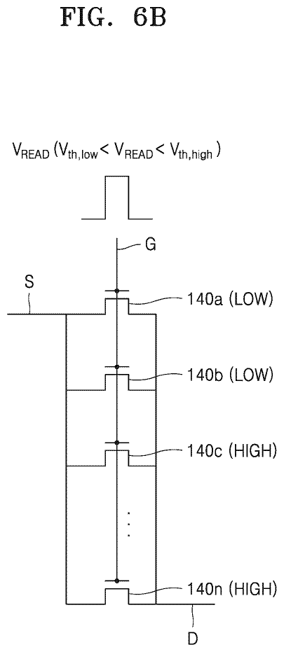

FIGS. 6A and 6B are diagrams illustrating a learning operation and an inference operation of a synapse device 140 according to at least one embodiment. Referring to FIG. 6A, a program voltage V_{PGM} may be applied to the gate terminal G of the synapse device 140 during a learning operation. The strength of the program voltage V_{PGM} may be determined according to a value of a weight to be recorded in the synapse device 140. For example, when the strength of the program voltage V_{PGM} is greater than the second coercive voltage Vc2 and less than the third coercive voltage Vc3 (that is, Vc2<V_{PGM}<Vc3), the first ferroelectric field effect transistor 140a and the second ferroelectric field effect transistor 140b may be in a first state having a first threshold voltage, and the third to n-th ferroelectric field effect transistors 140c, . . . and 140n may be in a second state having a second threshold voltage.

Referring to FIG. 6B, a read voltage V_{READ} may be applied to the gate terminal G of the synapse device 140 during an inference operation. The read voltage V_{READ} may be a voltage greater than the first threshold voltage V_{th, low} and lower than the second threshold voltage V_{th, high} (that is, V_{th, low}<V_{READ}<V_{th, high}). When the first ferroelectric field effect transistor 140a and the second ferroelectric field effect transistor 140b each have the first state, and a read voltage V_{READ} is applied thereto, the first ferroelectric field effect transistor 140a and the second ferroelectric field effect transistor 140b may be turned on to become a low resistance state LOW, while the third to n-th ferroelectric field effect transistors 140c, . . . , and 140n may be turned off to become a high resistance state HIGH.

When the read voltage V_{READ} is applied to the gate terminal G, the electrical conductance of the synapse device 140 may be determined by the number of turned-on ferroelectric field effect transistors. For example, if the electrical conductance of one turned-on ferroelectric field effect transistor is G, the electrical conductance of the synapse device 140 may be kG when k ferroelectric field effect transistors are turned on. Therefore, when the read voltage V_{READ} is applied to the gate terminal G of the synapse device 140 and the current flowing between the source terminal S and the drain terminal D of the synapse device 140 is measured, and thus the weight value recorded in the synapse device 140 may be read.

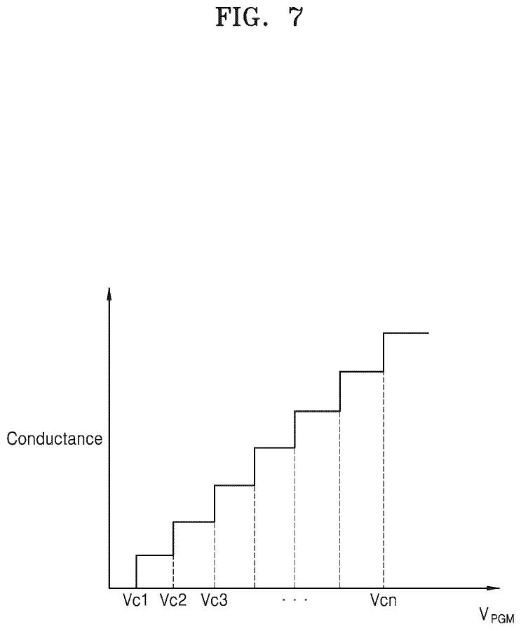

FIG. 7 is a graph showing the relationship between a program voltage V_{PGM} applied to a synapse device 140 and electrical conductance of the synapse device 140 according to at least one embodiment. The electrical conductance of the synapse device 140 is the electrical conductance when the read voltage V_{READ} is applied to the gate terminal G of the synapse device 140 in the inference operation. In addition, in the following description, all ferroelectric field effect transistors in the synapse device 140 have a second state in the initial stage. Referring to FIG. 7, when the program voltage V_{PGM} is 0 or negative n-th coercive voltage −Vcn, all ferroelectric field effect transistors of the synapse device 140 are turned off in inference operation, and the electrical conductance of the synapse device 140 becomes 0 (0th electrical conductance). When the program voltage V_{PGM} increases sequentially from the first coercive voltage Vc1 to the n-th coercive voltage Vcn, the electrical conductance of the synapse device 140 in the inference operation increases step by step to G (first electrical conductance), 2G (second electrical conductance), . . . , and nG (n-th electrical conductance). In this regard, the synapse device 140 may store a weight value in a discrete form or in a quantized form. For example, when the synapse device 140 includes n ferroelectric field effect transistors, the synapse device 140 may store n+1 distinct weight values. In other words, the synapse device 140 may have one of the discontinuous n+1 electrical conductance (i.e., discontinuous 0th to n-th electrical conductance) corresponding to n+1 distinct weight values according to the program voltage V_{PGM} applied thereto.

In general, the on-resistance or turn-on electrical conductance of field effect transistors may be mainly affected by the material and size of the channel region. Even if the first to n-th ferroelectric field effect transistors 140a, 140b, 140c, . . . , and 140n have different coercive voltages, the first to n-th ferroelectric field effect transistors 140a, 140b, 140c, . . . , and 140n may have the same on-resistance or the same electrical conductance at turn-on time when the first to n-th ferroelectric field effect transistors 140a, 140b, 140c, . . . , and 140n are the same material and size as the material and size of the channel region 144. Accordingly, the electrical conductance of the first to n-th ferroelectric field effect transistors 140c, . . . , and 140n in the synapse device 140 when turned on according to at least one embodiment may be almost the same. In this case, in the electrical conductance graph illustrated in FIG. 7, the heights of the steps may be almost the same. This means that the synapse device 140 has a very linear response characteristic. In other words, in the electrical conductance graph illustrated in FIG. 7, centers of a plurality of steps may be placed on one straight line segment. Alternatively, the 0th to n-th electrical conductance representing each of the n+1 distinct weight values to be recorded in the synapse device 140 have discontinuous values that form an arithmetical progression.

Therefore, the synapse device 140 may have one of a plurality of discrete or discontinuous electrical conductance (or weight) values that are distinguished from each other depending on the strength of the program voltage V_{PGM} applied thereto. A plurality of discrete or discontinuous electrical conductance (or weight) values that the synapse device 140 may have may be placed on a substantial straight line segment. In other words, a plurality of discrete or discontinuous electrical conductance (or weight) values that the synapse device 140 may have may form an arithmetic progression. It may be seen that the synapse device according to the embodiments disclosed in this regard may have quantized linear response characteristics when considering an arrangement on a straight line of discrete or discontinuous electrical conductance (or weight) values, although not having continuous electrical conductance (weight) values.

As described so far, in the case of the synapse device 140 according to the embodiments, the ferroelectric layer 145 of each of the first to n-th ferroelectric field effect transistors 140a, 140b, 140c, . . . , and 140n is completely polarization-switched to have each of the first to n-th ferroelectric field effect transistors 140a, 140b, 140c, . . . , and 140n have only one of the first and second states. In addition, in learning and inference operations, each of the first to n-th ferroelectric field effect transistors 140a, 140b, 140c, . . . , and 140n is completely turned on or completely turned off. Accordingly, the synapse device 140 according to at least one embodiment may have excellent linear response characteristics with respect to the applied program voltage. The neural network apparatus 100 including the synapse device 140 may secure excellent multi-level characteristics, excellent linearity, and reliability. In addition, as shown in FIGS. 6A and 7, since the program voltage may be set within a range between two adjacent coercive voltages, the operation reliability of the synapse device 140 is not affected even though the strength of the program voltage is not precisely controlled. Accordingly, a relatively wide tolerance may be allowed to the voltage supplied by the driving circuit, particularly, the program line driver 120 illustrated in FIG. 1.

Meanwhile, the first to n-th ferroelectric field effect transistors 140a, 140b, 140c, . . . , and 140n may all have the same first threshold voltage and the same second threshold voltage in the synapse device 140, but due to the difference in the ferroelectric layer 145, there may be a slight deviation between the first threshold voltages and between the second threshold voltages of the first to n-th ferroelectric field effect transistors 140a, 140b, 140c, . . . , and 140n. However, even in this case, the difference between the maximum first threshold voltage among the first threshold voltages of the first to n-th ferroelectric field effect transistors 140a, 140b, 140c, . . . , and 140n and the minimum second threshold voltage among the second threshold voltages of the first to n-th ferroelectric field effect transistors 140a, 140b, 140c, . . . , and 140n may be sufficiently large. Thus, the case wherein some of the first to n-th ferroelectric field effect transistors 140a, 140b, 140c, . . . , and 140n are incorrectly turned off or incorrectly turned on in the inference operation is prevented and/or mitigated. In other words, the strength of the read voltage applied to the synapse device 140 in the inference operation may be greater than the strength of the maximum first threshold voltage among the first threshold voltages of the first to n-th ferroelectric field effect transistors 140a, 140b, 140c, . . . , and 140n, and less than the strength of the minimum second threshold voltage among the second threshold voltages of the first to n-th ferroelectric field effect transistors 140a, 140b, 140c, . . . , and 140n.

Furthermore, since the first to n-th ferroelectric field effect transistors 140a, 140b, 140c, . . . , and 140n have sufficiently high coercive voltages, the strength of the minimum coercive voltage among the coercive voltages of the first to n-th ferroelectric field effect transistors 140a, 140b, 140c, . . . , and 140n is greater than the strength of the maximum second threshold voltage among the second threshold voltages of the first to n-th ferroelectric field effect transistors 140a, 140b, 140c, . . . , and 140n. Accordingly, during the inference operation, the weight value recorded in the synapse device 140 may not change.

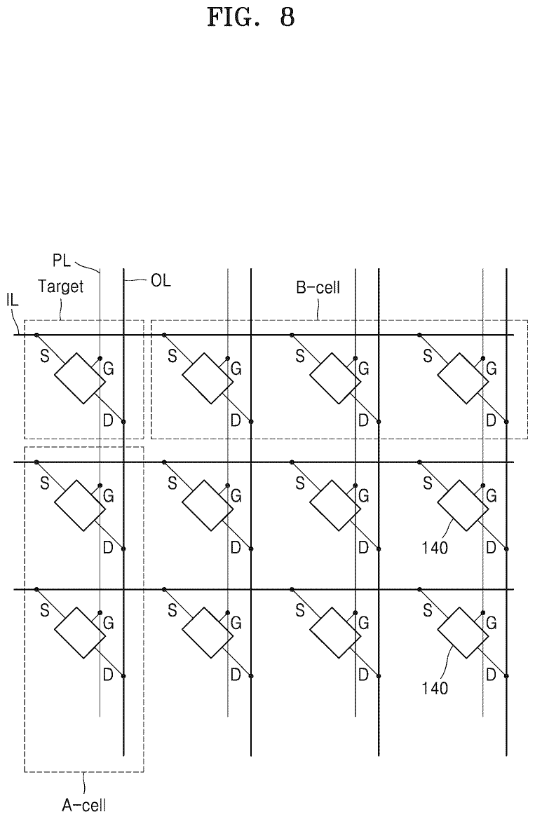

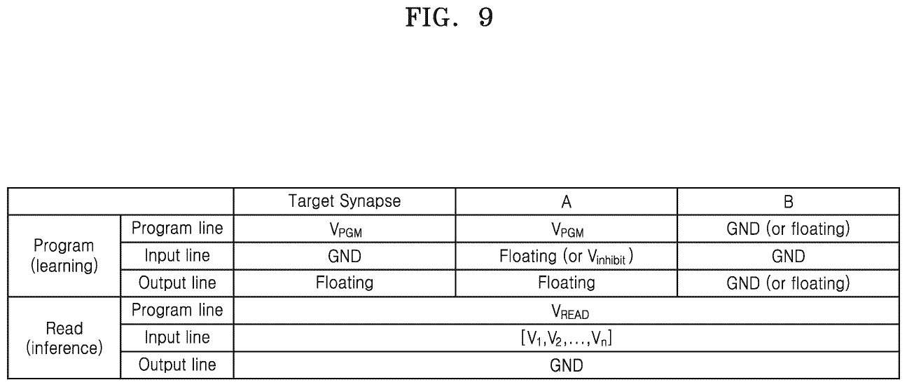

FIGS. 8 and 9 are diagrams illustrating a learning operation and an inference operation of a neural network apparatus 100 according to at least one embodiment.

In the learning operation, while changing the weight value of one target synapse device, appropriate voltages may be applied to the plurality of program lines PL, the plurality of input lines IL, and the plurality of output lines OL so that the weight values of other synapse devices sharing lines with the target synapse device do not change. Referring to FIG. 8, an A-cell includes synapse devices that share the program line PL with the target synapse device, and a B-cell includes synapse devices that share the input line IL with the target synapse device. Hereinafter, for purposes of description, the synapse devices in the A-cell are referred to as “A-cell synapse devices”, and the synapse devices in the B-cell are referred to as “B-cell synapse devices”.

Referring to FIG. 9, in a learning operation, a program voltage V_{PGM} is supplied to a program line PL to which a target synapse device is connected. The input line IL to which the target synapse device is connected may be grounded so that current flows from the gate of the ferroelectric field effect transistors in the target synapse device to the ferroelectric layer thereof. In addition, the output line OL connected to the target synapse device may be in a floating state so that current does not flow between the source and drain of the ferroelectric field effect transistors in the target synapse device. This operation may be performed by controlling the input circuit 110, the program line driver 120, and the output circuit 130 by the control circuit 150 shown in FIG. 1.

The program voltage V_{PGM} is also applied to the gates of the A-cell synapse devices sharing the program line PL with the target synapse device. In this case, the input line IL and the output line OL to which the A-cell synapse devices are connected may be in a floating state so that current does not flow from the gates of the ferroelectric field-effect transistors in the A-cell synapse devices to the ferroelectric layer thereof. Alternatively, an inhibit voltage may be supplied to an input line IL to which A-cell synapse devices are connected. The inhibit voltage V_{inhibit} may be, for example, the same voltage as the program voltage V_{pgm}.

The remaining program lines PL to which the target synapse device is not connected may be grounded and/or in a floating state. Accordingly, the gates of the B-cell synapse devices may be grounded or in a floating state. Since the B sub-cell synapse devices share an input line IL with the target synapse device, the source of the B sub-cell synapse devices may be grounded. The output line OL to which the B-cell synapse devices are connected may be grounded or in a floating state.

In an inference operation, all output lines OL may be grounded. In addition, a read voltage V_{READ} may be supplied to all program lines PL. Different input signals or input voltages may be supplied to the plurality of input lines IL. For example, when the neural network apparatus 100 includes first to n-th input lines, a first input voltage V1 may be supplied to the first input line, a second input voltage V2 different from the first input voltage V1 may be supplied to the second input line, and a n-th input voltage Vn may be supplied to the n-th input line. In this case, the sum of the currents flowing through all synapse devices 140 connected to one output line OL may be provided to the output circuit 130 through the one output line OL. In another embodiment, an input voltage may be sequentially supplied to one input line. For example, a predetermined input voltage may be supplied to the first input line, and the remaining input lines may be grounded or in a floating state. Then, a predetermined input voltage is supplied to the second input line, and the remaining input lines may be grounded or in a floating state.

Meanwhile, when the neural network apparatus 100 is to be completely reset, all input lines IL may be grounded, all output lines OL may be in a floating state, and a negative n-th coercive voltage −Vcn may be applied to all the program lines PL.

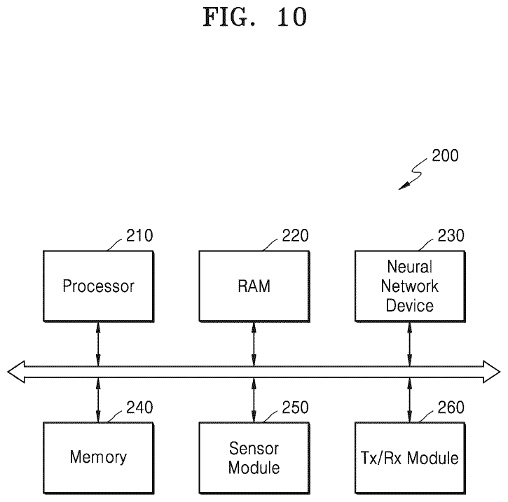

FIG. 10 is a block diagram schematically illustrating an example structure of an electronic apparatus including a neural network apparatus. Referring to FIG. 10, the electronic apparatus 200 may analyze input data in real time based on a neural network to extract valid information, determine a situation based on the extracted information, or control configurations of a device equipped with the electronic apparatus 200. For example, the electronic apparatus 200 may be applied to a robot device such as a drone, an advanced driver assistance system (ADAS), or the like, a smart television (TV), a smartphone, a medical device, a mobile device, an image display device, a measurement device, and an internet of things (IoT) device, and/or the like, and may be mounted on at least one of various types of devices.

The electronic apparatus 200 may include a processor 210, a random access memory (RAM) 220, a neural network apparatus 230, a memory 240, a sensor module 250, and a communication module 260. The electronic apparatus 200 may further include an input/output module, a security module, a power control device, and the like. Some of the hardware components of the electronic apparatus 200 may be mounted on at least one semiconductor chip.

The processor 210 controls the overall operation of the electronic apparatus 200. The processor 210 may include one processor core or a plurality of processor cores (e.g., Multi-Core). The processor 210 may process or execute programs and/or data stored in the memory 240. In some embodiments, the processor 210 may control the function of the neural network apparatus 230 by executing programs stored in the memory 240. The processor 210 may be implemented as a central processing unit (CPU), a graphics processing unit (GPU), an application processor (AP), and/or the like.

The RAM 220 may temporarily store programs, data, or instructions. For example, programs and/or data stored in the memory 240 may be temporarily stored in the RAM 220 according to the control or boot code of the processor 210. The RAM 220 may be implemented as a memory such as dynamic RAM (DRAM), static RAM (SRAM), or the like.

The neural network apparatus 230 may perform an operation of the neural network based on the received input data and generate an information signal based on the execution result. The neural network may include, but is not limited to, CNN, RNN, FNN, long short-term memory (LSTM), stacked neural network (SNN), state-space dynamic neural network (SSDNN), deep belief networks (DBN), restricted Boltzmann machine (RBM), and the like.

The neural network apparatus 230 may be a hardware accelerator itself dedicated to a neural network or an apparatus including the same. The neural network apparatus 230 may perform a read or write operation as well as an operation of the neural network.

The neural network apparatus 230 may correspond to the neural network apparatus 100 according to the embodiment illustrated in FIG. 1. Since the neural network apparatus 230 may implement weights having linear state change characteristics, accuracy of neural network operations performed by the neural network apparatus 230 may be increased, and a more sophisticated neural network may be implemented.

The information signal may include one of various types of recognition signals such as a voice recognition signal, an object recognition signal, an image recognition signal, a biometric information recognition signal, and the like. For example, the neural network apparatus 230 may receive frame data included in the video stream as input data and generate, from frame data, a recognition signal for an object included in an image represented by the frame data. However, the neural network apparatus is not limited thereto, and the neural network apparatus 230 may receive various types of input data and generate a recognition signal according to the input data according to the type or function of the device on which the electronic apparatus 200 is mounted.

The neural network apparatus 230 may perform, for example, machine learning model such as linear regression, logistic regression, statistical clustering, Bayesian classification, decision trees, principal component analysis, and/or expert system, and/or machine learning model of ensemble techniques, etc., such as random forest. The machine learning model may be used to provide various services such as, for example, image classification service, user authentication service based on biometric information or biometric data, advanced driver assistance system (ADAS), voice assistant service, automatic speech recognition (ASR) service, and/or the like.

The memory 240 is a storage place for storing data and may store an operating system (OS), various programs, and various pieces of data. In at least one embodiment, the memory 240 may store intermediate results generated during the operation of the neural network apparatus 230.

The memory 240 may be a DRAM, but is not limited thereto. The memory 240 may include at least one of a volatile memory and a nonvolatile memory. The nonvolatile memory includes read-only memory (ROM), programmable ROM (PROM), electrically programmable ROM (EPROM), electrically erasable and programmable ROM (EEPROM), flash memory, phase-change ROM (PROM), magnetic ROM (MROM), resistive ROM (RROM), ferroelectric ROM (FROM), and the like. The volatile memory includes dynamic RAM (DRAM), static RAM (SRAM), synchronous DRAM (SDRAM), phase-change RAM (PRAM), magnetic RAM (MRAM), resistive RAM (RRAM), and ferroelectric RAM (FeRAM). In at least one embodiment, the memory 240 may include at least one of a hard disk drive (HDD), a solid state drive (SSD), a compact flash (CF), a secure digital (SD), a micro secure digital (Micro-SD), a mini secure digital (Mini-SD), and a memory stick.

The sensor module 250 may collect information around a device on which the electronic apparatus 200 is mounted. The sensor module 250 may sense or receive a signal (e.g., an image signal, a voice signal, a magnetic signal, a bio signal, a touch signal, etc.) from the outside of the electronic apparatus 200 and convert the sensed or received signal into data. To this end, the sensor module 250 may include at least one of various types of sensing devices such as a sensing device, for example, a microphone, an imaging device, an image sensor, a light detection and ranging (LIDAR) sensor, an ultrasonic sensor, an infrared sensor, a biosensor, a touch sensor, and/or the like.

The sensor module 250 may provide the converted data to the neural network apparatus 230 as input data. For example, the sensor module 250 may include an image sensor, generate a video stream by photographing an external environment of the electronic device 200, and sequentially provide the continuous data frame of the video stream to the neural network apparatus 230 as input data. However, embodiments are not limited thereto, and the sensor module 250 may provide various types of data to the neural network apparatus 230.

The communication module 260 may include various wired or wireless interfaces capable of communicating with an external device. For example, the communication module 260 may include a wired local area network (LAN), a wireless local area network (WLAN) such as a wireless fidelity (Wi-Fi), a wireless personal area network (WPAN) such as Bluetooth, a wireless universal serial bus (USB), Zigbee, near field communication (NFC), radio-frequency identification (RFID), power line communication (PLC), and a communication interface capable of connecting to a mobile cellular network, such as 3rd generation (3G), 4th generation (4G), long term evolution (LTE), and/or the like.

Although the synapse device including the ferroelectric field effect transistor and the neural network apparatus including the same have been described with reference to the embodiments illustrated in the drawings, the synapse device according to the embodiments may have one of a plurality of discrete weight values distinguished from each other according to the intensity of a program voltage applied thereto, and the plurality of discrete weight values may be placed on substantially straight line segments. In this regard, the synapse device according to the embodiments has excellent quantized linear response characteristics to the applied voltage, considering the straight-line arrangement of discontinuous weight values, although it does not have a continuous weight value. Therefore, the neural network apparatus including a synapse device according to the embodiments may secure excellent multi-level characteristics, linearity, and reliability.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A synapse device comprising:
a first ferroelectric field effect transistor including a source region, a drain region, and a gate electrode; and
a second ferroelectric field effect transistor including a source region, a drain region, and a gate electrode,
wherein the gate electrodes of the first ferroelectric field effect transistor and the second ferroelectric field effect transistor are electrically connected to each other, the source regions of the first ferroelectric field effect transistor and the second ferroelectric field effect transistor are electrically connected to each other, and the drain regions of the first ferroelectric field effect transistor and the second ferroelectric field effect transistor are electrically connected to each other, and
the first ferroelectric field effect transistor has a first coercive voltage, and the second ferroelectric field effect transistor has a second coercive voltage greater than the first coercive voltage.

2. The synapse device of claim 1, wherein the first ferroelectric field effect transistor and the second ferroelectric field effect transistor are each configured to be switchable between a first state having a first threshold voltage and a second state having a second threshold voltage that is greater than the first threshold voltage.

3. The synapse device of claim 1, wherein each of the first ferroelectric field effect transistor and the second ferroelectric field effect transistor further comprises:
a channel region between the source region and the drain region; and
a ferroelectric layer between the channel region and the gate electrode,
wherein the gate electrode faces the channel region.

4. The synapse device of claim 3, wherein the ferroelectric layer of the first ferroelectric field effect transistor has a first thickness, and the ferroelectric layer of the second ferroelectric field effect transistor has a second thickness that is greater than the first thickness.

5. The synapse device of claim 3, wherein the ferroelectric layer of the first ferroelectric field effect transistor and the ferroelectric layer of the second ferroelectric field effect transistor have at least one of different ferroelectric materials from each other or different compositions from each other.

6. The synapse device of claim 3, wherein the ferroelectric layer of the first ferroelectric field effect transistor and the ferroelectric layer of the second ferroelectric field effect transistor are heat-treated in different heat treatment atmospheres or at different heat treatment temperatures.

7. The synapse device of claim 3, wherein the channel region of the first ferroelectric field effect transistor and the channel region of the second ferroelectric field effect transistor have substantially the same material and size as each other.

8. The synapse device of claim 1, further comprising:
a gate terminal electrically connected to the gate electrodes of the first ferroelectric field effect transistor and the second ferroelectric field effect transistor through a first shared wire;
a source terminal electrically connected to the source regions of the first ferroelectric field effect transistor and the second ferroelectric field effect transistor through a second shared wire; and
a drain terminal electrically connected to the drain regions of the first ferroelectric field effect transistor and the second ferroelectric field effect transistor through a third shared wire.

9. The synapse device of claim 1, wherein the first ferroelectric field effect transistor and the second ferroelectric field effect transistor have substantially the same electrical conductance when turned on.

10. The synapse device of claim 1, wherein the synapse device is configured to switch between a plurality of discrete electrical conductance values based on a voltage applied to the synapse device and the plurality of discrete electrical conductance values are distinguished from each other.

11. A neural network apparatus comprising:
a plurality of input lines;
a plurality of output lines;
a plurality of program lines; and
a two-dimensional array of synapse devices, wherein each of the synapse devices is electrically connected to a corresponding input line among the plurality of input lines, a corresponding program line among the plurality of program lines, and a corresponding output line among the plurality of output lines,
wherein each of the synapse devices comprises
a first ferroelectric field effect transistor including a source region, a drain region, and a gate electrode, and
a second ferroelectric field effect transistor including a source region, a drain region, and a gate electrode,
wherein the gate electrodes of the first ferroelectric field effect transistor and the second ferroelectric field effect transistor are electrically connected to each other, the source regions of the first ferroelectric field effect transistor and the second ferroelectric field effect transistor are electrically connected to each other, the drain regions of the first ferroelectric field effect transistor and the second ferroelectric field effect transistor are electrically connected to each other, and
the first ferroelectric field effect transistor has a first coercive voltage, and the second ferroelectric field effect transistor has a second coercive voltage that is greater than the first coercive voltage.

12. The neural network apparatus of claim 11, wherein the first ferroelectric field effect transistor and the second ferroelectric field effect transistor are each configured to be switchable between a first state having a first threshold voltage and a second state having a second threshold voltage that is greater than the first threshold voltage.

13. The neural network apparatus of claim 11, wherein each of the first ferroelectric field effect transistor and the second ferroelectric field effect transistor further comprises:
a channel region between the source region and the drain region; and
a ferroelectric layer between the channel region and the gate electrode,
wherein the gate electrode faces the channel region, and
the ferroelectric layer of the first ferroelectric field effect transistor has a first thickness, and the ferroelectric layer of the second ferroelectric field effect transistor has a second thickness that is greater than the first thickness.

14. The neural network apparatus of claim 11, wherein each of the first ferroelectric field effect transistor and the second ferroelectric field effect transistor further comprises:
a channel region between the source region and the drain region; and
a ferroelectric layer between the channel region and the gate electrode,
wherein the gate electrode is faces the channel region, and
the ferroelectric layer of the first ferroelectric field effect transistor and the ferroelectric layer of the second ferroelectric field effect transistor have at least one of different ferroelectric materials from each other or different compositions from each other.

15. The neural network apparatus of claim 11, wherein each of the first ferroelectric field effect transistor and the second ferroelectric field effect transistor further comprises:
a channel region between the source region and the drain region; and
a ferroelectric layer between the channel region and the gate electrode,
wherein the gate electrode faces the channel region, and
the ferroelectric layer of the first ferroelectric field effect transistor and the ferroelectric layer of the second ferroelectric field effect transistor are heat-treated in different heat treatment atmospheres from each other or at different heat treatment temperatures from each other.

16. The neural network apparatus of claim 13, wherein the channel region of the first ferroelectric field effect transistor and the channel region of the second ferroelectric field effect transistor have substantially the same material and size as each other.

17. The neural network apparatus of claim 11, wherein the synapse devices each further include a gate terminal, a source terminal, and a drain terminal, wherein
the gate electrodes of the first ferroelectric field effect transistor and the second ferroelectric field effect transistor are electrically connected to the gate terminal through a first shared wire,
the source regions of the first ferroelectric field effect transistor and the second ferroelectric field effect transistor are electrically connected to the source terminal through a second shared wire, and
the drain regions of the first ferroelectric field effect transistor and the second ferroelectric field effect transistor are electrically connected to the drain terminal through a third shared wire.

18. The neural network apparatus of claim 17, wherein the gate terminal of each of the synapse devices is electrically connected to the corresponding program line, the source terminal of each of the synapse devices is electrically connected to the corresponding input line, and the drain terminal of each of the synapse devices is electrically connected to the corresponding output line.

19. The neural network apparatus of claim 11, wherein the first ferroelectric field effect transistor and the second ferroelectric field effect transistor have substantially the same electrical conductance when turned on.

20. The neural network apparatus of claim 11, further comprising:
an input circuit configured to provide an input voltage to the plurality of input lines;
a program line driver configured to provide at least one of a program voltage or a read voltage to the plurality of program lines; and
an output circuit configured to output signals from the plurality of output lines,
wherein each of the synapse devices is configured to switch between at least a 0th electrical conductance, a first electrical conductance, and a second electrical conductance based on a voltage applied to the synapse device, and
values of the 0th electrical conductance to the second electrical conductance are discrete values configured to represent an arithmetical progression.
